(19) United States
(12) Patent Application Publication
(10) Pub. No.: US 2025/0314714 A1
(43) Pub. Date: Oct. 9, 2025

(54) DC LOAD FAULT DETECTION FOR SWITCHED BUSSES

(71) Applicant: ASSA ABLOY Access and Egress Hardware Group, Inc., New Haven, CT (US)

(72) Inventors: Matthew Conway, Monroe, NC (US); Daniel Dunham, Monroe, NC (US)

(73) Assignee: ASSA ABLOY Access and Egress Hardware Group, Inc., New Haven, CT (US)

(21) Appl. No.: 19/169,553

(22) Filed: Apr. 3, 2025

Related U.S. Application Data
(60) Provisional application No. 63/575,192, filed on Apr. 5, 2024.

(51) Int. Cl. G01R 31/52; G01R 19/165; G01R 31/58

(52) U.S. Cl. CPC G01R 31/52; G01R 19/16533; G01R 31/58

(57) ABSTRACT

There is provided a circuit for detecting a voltage fault. The circuit comprises filtering circuitry comprising a first time constant applicable to charging of the filtering circuitry and a second time constant different than the first time constant applicable to discharging of the filtering circuitry. The filtering circuitry filters input signals having a frequency greater than a threshold and passes input signals having a frequency less than the threshold. The circuit further comprises threshold detecting circuitry for determining whether signals output from the filtering circuitry exceeds a threshold voltage, wherein exceedance of the threshold voltage is indicative of the voltage fault.

### CROSS-REFERENCE TO RELATED APPLICATIONS

This application claims the benefit under 35 U.S.C. § 119(e) of U.S. Provisional App. No. 63/575,192, entitled “DC LOAD FAULT DETECTION FOR SWITCHED BUSSES”, filed Apr. 5, 2024 under Attorney Docket No. A1174.70222US00, which is hereby incorporated by reference in its entirety herein.

### FIELD

Aspects of the technology described herein provide for circuitry configured to detect a DC load fault, and in particular, DC load fault detection circuitry for switched busses.

### BACKGROUND

Faults are abnormal conditions that may occur in circuitry used to control and/or power a device. An expected path for current flow in the circuitry is interrupted when a fault occurs. A fault may occur in circuitry for one or more reasons, including failure of hardware, software, and/or firmware, environmental conditions, or human error. Occurrence of a fault can lead to inability to operate the device partially or fully, damage to the device, and may in some cases, lead to dangerous conditions such as undesired operation, electrical shock, fire, or other hazards.

### SUMMARY

According to some embodiments, there is provided a circuit for detecting a voltage fault, the circuit comprising: filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and threshold detecting circuitry for determining whether signals output from the filtering circuitry exceeds a threshold voltage, wherein exceedance of the threshold voltage is indicative of the voltage fault.

According to some embodiments, there is provided a method of manufacturing a circuit for detecting a voltage fault, the method comprising: providing filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and coupling threshold detecting circuitry to an output of the filtering circuitry, the threshold detecting circuitry for determining whether signals output from the filtering circuitry exceeds a threshold voltage, wherein exceedance of the threshold voltage is indicative of the voltage fault.

According to some embodiments, there is provided a method for detecting a voltage fault, the method comprising: filtering, with filtering circuitry comprising a first time constant applicable to charging of the filtering circuitry and a second time constant different than the first time constant applicable to discharging of the filtering circuitry, input signals having a frequency greater than a threshold and passing input signals having a frequency less than the threshold; determining, with threshold detecting circuitry, whether signals output from the filtering circuitry exceeds a threshold voltage; and detecting, based on exceedance of the threshold voltage, the voltage fault.

According to some embodiments, there is provided a system comprising: a device powered by power circuitry; and a circuit for detecting a voltage fault in the power circuitry, the circuit comprising: filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and threshold detecting circuitry for determining whether signals output from the filtering circuitry exceeds a threshold voltage, wherein exceedance of the threshold voltage is indicative of the voltage fault.

### BRIEF DESCRIPTION OF THE DRAWINGS

Various aspects and embodiments will be described with reference to the following figures. It should be appreciated that the figures are not necessarily drawn to scale. For purposes of clarity, not every component may be labeled in every drawing. In the drawings:

FIG. 1 illustrates an example circuit for detecting a voltage fault, according to some embodiments of the technology described herein.

FIG. 2 illustrates an example method for detecting a voltage fault, according to some embodiments of the technology described herein.

FIG. 3 illustrates an example method for manufacturing a circuit for detecting a voltage fault, according to some embodiments of the technology described herein.

FIG. 4 illustrates another example circuit for detecting a voltage fault, according to some embodiments of the technology described herein.

FIG. 5 illustrates another example circuit for detecting a voltage fault, according to some embodiments of the technology described herein.

FIG. 6. illustrates another example circuit for detecting a voltage fault, according to some embodiments of the technology described herein.

FIG. 7 illustrates another example circuit for detecting a voltage fault, according to some embodiments of the technology described herein.

FIG. 8A illustrates an example graph illustrating voltage across the capacitor C1 of the fault detection circuit of FIG. 7, according to some embodiments of the technology described herein.

FIG. 8B illustrates an example graph illustrating voltage input to the filtering circuitry of the fault detection circuit of FIG. 7, according to some embodiments of the technology described herein.

FIG. 8C illustrates another example graph illustrating voltage across the capacitor C1 of the fault detection circuit of FIG. 7, according to some embodiments of the technology described herein.

FIG. 8D illustrates another example graph illustrating voltage input to the filtering circuitry of the fault detection circuit of FIG. 7, according to some embodiments of the technology described herein.

FIG. 9 illustrates another example circuit for detecting a voltage fault, according to some embodiments of the technology described herein.

FIG. 10 illustrates another example circuit for detecting a voltage fault, according to some embodiments of the technology described herein.

FIG. 11A illustrates another example circuit for detecting a voltage fault, according to some embodiments of the technology described herein.

FIG. 11B illustrates the example circuit of FIG. 11A with annotations illustrating components of the dual time constant filter, according to some embodiments of the technology described herein.

FIG. 12 illustrates an example of a system including a circuit for detecting a voltage fault, according to some embodiments of the technology described herein.

### DETAILED DESCRIPTION

Aspects of the technology described herein relate to devices and techniques for detecting a fault across a load. For example, the techniques for detecting a fault may be implemented electronically in circuitry. The fault may be a DC voltage fault across a load on a switched DC voltage bus, and in particular, on a high frequency switched DC voltage bus.

In electronics, a load is an electrical component or portion of a circuit that consumes electric power. For example, a load may comprise a device such as a motor, a heater, or a lightbulb. Driving a load can include providing power to the load. In some cases, a fault may occur in circuitry due to unforeseen circumstances. For example, a component of the circuitry (e.g., a transistor) may become inoperable and/or an error in programming of the circuitry may cause a component of the circuitry to operate irregularly.

The occurrence of a fault may create a short in the circuitry instead of driving the load. When the circuitry shorts, current in the circuitry may bypass one or more components of the circuitry in favor of a path that has little to no resistance. Faults, including short circuits, can damage the circuitry and in some cases, may present dangerous conditions. Some devices may provide protections aiming to prevent faults from occurring. The aspects of the technology described herein provide a technique for detecting faults that would power the load. When a fault is detected, one or more actions can be taken to prevent or mitigate damage resulting from the fault.

A duty cycle, also referred to as a duty factor, is the ratio of time that a load or circuit is on compared to the time the load or circuit is off. The duty cycle can be expressed as a percentage of on time (e.g., a duty cycle of 75% is on 75% of the time and off 25% of the time). Loads or circuits may be considered to have a high duty cycle if the load or circuit is on more often than not. As described herein, analog electronics may have difficulty distinguishing between filtered pulse width modulation (PWM) signals and signals arising from a DC fault, particularly so for circuits having a duty cycle greater than 80%.

A switched duty cycle, as used herein, refers to a load or circuit that is not always on. In other words, a switched duty cycle has a value less than 100%. The devices and techniques described herein for detecting a fault across a load are applicable to switched duty cycles. The inventors have recognized that the devices and techniques for detecting a fault described herein may be particularly beneficial for switched high duty cycles. For example, the aspects of the technology described herein can be applied to duty cycles less than, but nearly, 100% (e.g., at least 80%, 85%, 90%, 95%, etc., but less than 100%). Accordingly, the techniques described herein can be applied to loads which are typically on, and only off for a short period of time.

The inventors have recognized that it can be difficult for analog electronics to differentiate high duty cycle switching from a DC fault. For example, when a switched signal (e.g., continuous ON-off cycles) is passed through a low pass filter with a threshold frequency lower than the switching frequency, the output is approximately the average voltage of the switched signal. This means a high duty cycle switched signal (for example, a duty cycle where the signal on 99% of the time and off 1% of the time), passed through a low-pass filter as described, would produce a voltage level that is approximately 99% of the DC voltage level (most controllers can exceed 99% on-time, making values like 99.9% possible). Because these values are so similar, differentiation between a DC fault and a signal from a high duty cycle switching bus under normal operation can be difficult.

The devices and techniques for detecting a fault described herein utilize circuitry that has a dual time constant. That is, the circuitry has a first time constant applicable to signals moving through the circuitry in a first direction, and a second time constant, different than the first time constant, applicable to signals moving through the circuitry in a second direction opposite the first direction. The first time constant may apply to charging of the circuitry and the second time constant may apply to discharging of the circuitry.

The second time constant applicable to discharging of the circuitry may be less than the first time constant applicable to charging of the circuitry such that discharging of the circuitry can be performed more rapidly than charging of the circuitry. As described herein, the inventors have recognized that this configuration is advantageous for switched high duty cycle devices, as the fast discharging of the circuitry allows for the filtering (e.g., blocking or preventing accumulation of charge) of high duty-cycle switched signals that would otherwise appear to be the same or very similar to a DC fault on the output of the filter while passing low frequency signals and a large frequency range of discharging signals. Accordingly, the circuitry described herein having a dual time constant can function as a low-pass filter (a low-side envelope follower). Advantageously, the circuitry described herein can differentiate a DC voltage fault from other signals, including high frequency signals which oscillate between on and off such as high duty cycle pulse width modulation (PWM) signals as well as constant polarity reversals.

Accordingly, there is provided herein a circuit for detecting a voltage fault, the circuit comprising filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold (e.g., low frequency charging signals as well as a wide range of discharging signals), and threshold detecting circuitry for determining whether signals output from the filtering circuitry exceeds a threshold voltage, wherein exceedance of the threshold voltage is indicative of the voltage fault.

According to some aspects, there is further provided a method for manufacturing a circuit for detecting a voltage fault. According to some aspects, there is provided a method for detecting a voltage fault, for example, using the circuitry described herein. According to some aspects, there is provided a system comprising a device powered by power circuitry and a circuit for detecting a voltage fault in the power circuitry.

The aspects and embodiments described above, as well as additional aspects and embodiments, are described further below. These aspects and/or embodiments may be used individually, all together, or in any combination, as the application is not limited in this respect.

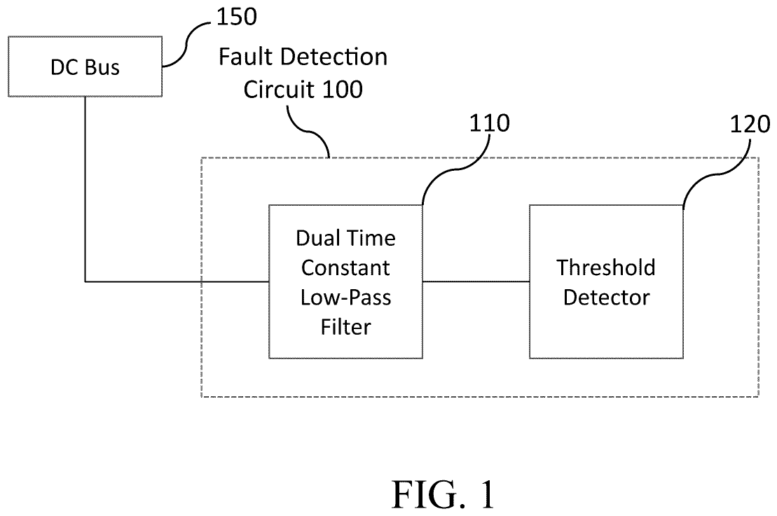

FIG. 1 illustrates an example circuit for detecting a voltage fault, according to some embodiments of the technology described herein. As shown in FIG. 1, the fault detection circuit comprises filtering circuitry 110 and threshold detecting circuitry 120.

The fault detection circuit 100 receives an input signal from DC bus 150. The input signal may be a signal from control circuitry configured to control (e.g., provide power) to a device. The control circuitry may comprise power circuitry. A fault may originate in the power circuitry. As such, providing signals from the power circuitry to the fault detection circuit 100 allows for detecting a fault in the power circuitry that provides power to the device.

The input signal is then provided to the filtering circuitry 110. The filtering circuitry 110 functions to filter (e.g., block or limit passage for example, by preventing accumulation thereof) certain input signals while allowing other input signals to pass. In particular, the filtering circuitry 110 passes signals which are indicative of a fault in power circuitry while filtering other signals (such as pulse width modulation signals) to prevent falsely detecting a fault in the power circuitry.

The fault detection circuit 100 further comprises threshold detecting circuitry 120. The threshold detecting circuitry 120 receives signals output from the filtering circuitry 110. The threshold detecting circuitry 120 functions to detect whether the signals output from the filtering circuitry meet and/or exceed a threshold. In some embodiments, exceedance of the threshold as detected by the threshold detecting circuitry 120 is indicative of a voltage fault in the power circuitry.

As described herein, the threshold detecting circuitry 120 may be implemented in various ways. For example, in some embodiments, the threshold detecting circuitry comprises a comparator, a logic-level device (e.g., a microcontroller input), and/or any other device that is capable of creating a digital on/off signal that switches when input to the device reaches a threshold.

As shown in FIG. 1, the filtering circuitry 110 comprises a dual time constant low-pass filter. In particular, the filtering circuitry 110 comprises at least two time constants which are dependent on the direction of signal propagation. For the filtering circuitry 110, a first time constant τ₁ of the filtering circuitry 110 is applicable while power is being applied to the load (e.g., when signals move from left to right and the filtering circuitry 110 is charging) and a second time constant τ₂ is applicable while power is not applied to the load (e.g., when signals move from right to left and the filtering circuitry 110 is discharging).

In some embodiments, the time constant τ₁ for charging of the filtering circuitry 110 is larger than the time constant τ₂ for discharging of the filtering circuitry 110, such that discharging of the filtering circuitry 110 occurs more rapidly than charging of the filtering circuitry 110. As described herein, the ability of the filtering circuitry 110 to rapidly discharge the filtering circuitry 110 limits accumulation of charge resulting from signals that oscillate on and off. The configuration of the filtering circuitry 110 having the direction dependent time constant allows the filtering circuitry to distinguish signals received during normal operation of the power circuitry (e.g., pulse width modulation signals which oscillate on and off) from signals that are indicative of a fault in the power circuitry (e.g., signals which do not oscillate on and off).

The fault detection circuitry described herein can be used for fault detection in various applications. As an illustrative example, as described herein, the fault detection circuitry is configured to detect a fault in circuitry for a switched DC voltage bus. That is, the device powered by the circuitry oscillates between being powered on (where it receives signals from the power circuitry) and being powered off (where it does not receive a signal from the power circuitry). As described herein, aspects of the fault detection circuitry may be particularly beneficial for a high duty cycle switched DC voltage bus. That is, the device is powered on more often than not, but there is still a portion of time when the device is powered off.

With the configuration of a switched DC voltage bus described herein, the signals provided to the device by the power circuitry to power the device oscillate between on and off. The signals which power the device can be considered, by the Fourier Transform, to be a combination of a DC component (of average value) and high frequency signals. By contrast, signals resulting from a DC voltage fault in the power circuitry do not oscillate on and off and therefore occur at a low frequency only. As described herein, the function of the filtering circuitry 110 is to filter signals which are not indicative of a DC voltage fault while allowing signals that are indicative of a DC voltage fault to pass through the circuitry. The circuitry requires filtering (or removing) DC values created by switched signals (as well as their high frequency components), while passing DC values that are not accompanied by high frequency signals. To accomplish this, the filtering circuitry 110 provides a low-pass filter to filter the high frequency signals which power the device (e.g., signals having a frequency greater than a threshold) and which are not indicative of a DC voltage fault while allowing the low frequency signals which are indicative of a DC voltage fault (e.g., signals having a frequency less and/or less than or equal to the threshold) to pass through the circuitry. As described herein, the low-pass filter may be implemented as a low-bandwidth low-pass filter to filter charging signals and a medium to high bandwidth low-pass filter to filter discharging signals, which provides a circuit that filters out high frequency signals as well as the DC signals embedded in the high frequency signals. Accordingly, the low-pass filter of the filtering circuitry 110 can facilitate prevention of false positive fault detection.

The direction dependent time constant of the filtering circuitry can facilitate implementation of the low-pass filter. As described herein, the fault detection circuitry may be implemented for a high duty cycle switched DC voltage bus. Accordingly, the power circuitry provides signals which power the device to be on more often than not. As described herein, the time constant τ₁ of the filtering circuitry 110 which is applicable to signals while power is being applied to the load (e.g., when the filtering circuitry 110 is charging) may be larger than the time constant τ₂ of the filtering circuitry 110 which is applicable to signals when power is not applied to the load (e.g., when the filtering circuitry 110 is discharging). Accordingly, discharging of the filtering circuitry 110 occurs more rapidly than charging of the filtering circuitry 110.

Charging of the filtering circuitry 110 occurs when signals which power the device are applied. For a high duty cycle switched DC bus, the device is on more often than not, and as such, charging of the filtering circuitry 110 occurs more often than discharging. Without any impediment or modification to the fault detection circuit 100, the more frequent charging of the filtering circuitry would result in accumulation of charge that eventually reaches the threshold level configured to trigger the threshold detecting circuitry 120 to detect a fault. This would be undesirable, as it would result in false positives.

The dual time constant of the filtering circuitry 100 prevents the accumulation of charge that would result in false positive fault detection. In particular, the dual time constants configure the filtering circuit to discharge rapidly while charging slowly. Accordingly, although charging of the circuitry occurs more often than discharging, the amount of charge accumulated during a charging period (while the device is on) can be approximately equal to the amount of charge discharged during a discharging period (while the device is off) so that charge from high frequency signals that power the device does not accumulate and unintentionally trigger the threshold detection circuitry 120.

By contrast, when a fault in the power circuitry occurs, an irregular spike in voltage is input to the fault detection circuit 100 from the DC bus 150. Because faults occur infrequently and do not oscillate between “on” and “off” states, the filtering circuitry 110 allows charge to accumulate until it reaches the threshold voltage that triggers the threshold detection circuitry 120. When the threshold voltage is met by the accumulation of charge due to the fault, the threshold detection circuitry 120 outputs a signal indicating that a fault has been detected.

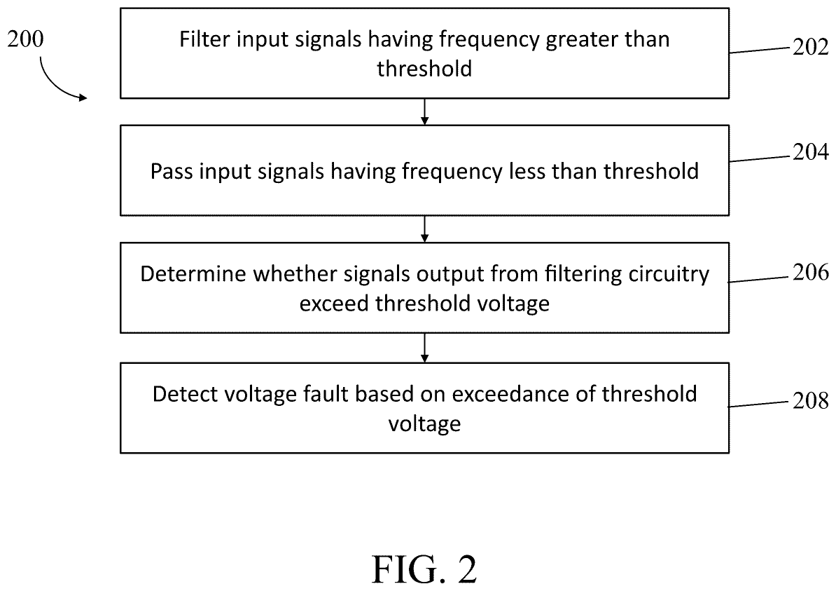

The fault detection circuit described herein may be implemented in a method for detecting a voltage fault. FIG. 2 illustrates an example method 200 for detecting a voltage fault, according to some embodiments of the technology described herein. The method 200 begins by filtering signals input to the fault detection circuit. For example, the filtering may be performed by the filtering circuitry 110, described herein. The signals input to the fault detection circuit may be input from power circuitry configured to power a device, where it is desired to monitor for and detect faults occurring in the power circuitry.

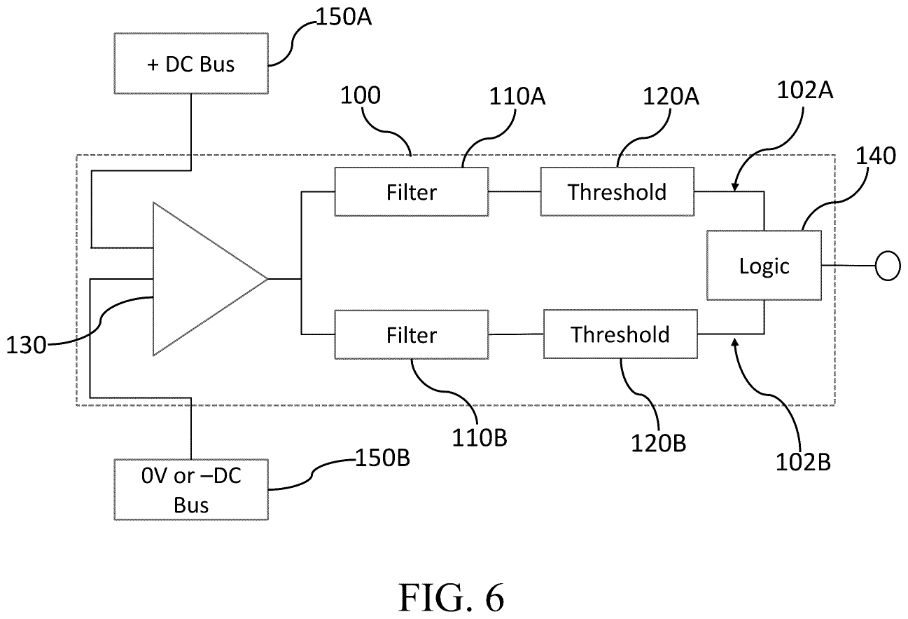

In particular, at act 202, input signals having a frequency greater than a threshold are filtered. In other words, input signals having the frequency greater than the threshold are prevented or limited from passing the filtering circuitry to the threshold detecting circuitry. As described herein, the filtering circuitry may function to prevent accumulation of charge from high frequency signals using the dual time constant configuration of the filtering circuitry which provides for discharging more rapidly than charging. Filtering input signals at act 202 may comprise filtering charging input signals having a frequency greater than a charging threshold and/or filtering discharging signals having a frequency greater than a discharging threshold. For example, in some embodiments, act 202 may comprise both filtering charging input signals having a frequency greater than a charging threshold and filtering discharging signals having a frequency greater than a discharging threshold such as where the filtering circuitry comprises a positive and negative branch as shown in FIG. 6, for example.

At act 204, input signals having a frequency less than the threshold are passed by the filtering circuitry. As described herein, the filtering circuitry may function to allow accumulation of charge from low frequency signals using the dual time constant configuration of the filtering circuitry. As low frequency signals do not frequently oscillate between “on” and “off”, or charging and discharging, the configuration of the filtering circuitry that facilitates rapid discharging and slow charging does not prevent the accumulation of charge from low frequency signals. Accordingly, low frequency signals are able to accumulate to reach a threshold voltage.

Passing input signals at act 204 may passing charging input signals having a frequency less than a charging threshold and/or passing discharging signals having a frequency less than a discharging threshold. For example, in some embodiments, act 204 may comprise both passing charging input signals having a frequency less than a charging threshold and passing discharging signals having a frequency less than a discharging threshold such as where the filtering circuitry comprises a positive and negative branch as shown in FIG. 6, for example.

At act 206, it is determined whether signals output from the filtering circuitry exceed a threshold voltage. Act 206 may be performed with the threshold detecting circuitry 120 described herein. For example, at act 206, the signal output from the filtering circuitry is compared to a threshold to determine whether the signal meets and/or exceeds the threshold. If the signal exceeds the threshold, a positive indication may be output from the threshold detecting circuitry. In some embodiments, if the signal meets the threshold, a positive indication may be output from the threshold detecting circuitry. The positive indication may indicate that the signal detected arose from a DC voltage fault, and therefore a fault has been detected in the power circuitry. If the signal does not meet and/or exceed the threshold (e.g., the signal is less than the threshold) the threshold detecting circuitry may output a negative indication. The negative indication may indicate that the signal detected did not arise from a DC voltage fault and therefore no fault has been detected.

At act 208, a voltage fault may be detected based on a determination that the signals output from the filtering circuitry exceed the threshold voltage made at act 206. For example, as described herein, signals which meet and/or exceed the threshold voltage may be determined to arise from a DC voltage fault, as the filtering circuitry is configured to only allow charge from low frequency signals to accumulate to the threshold level. Because DC voltage faults generate low frequency signals, the accumulation of charge, which in turn creates the signal which exceeds the threshold voltage as detected at act 206, is possible for signals arising from DC voltage faults. By contrast, high frequency signals such as pulse width modulation signals that arise in the normal operation of the device are prevented from accumulating the charge sufficient to exceed the threshold voltage. Accordingly, when the signals output from the filtering circuitry are determined to meet and/or exceed the threshold voltage, it can be determined that a voltage fault has occurred in the power circuitry.

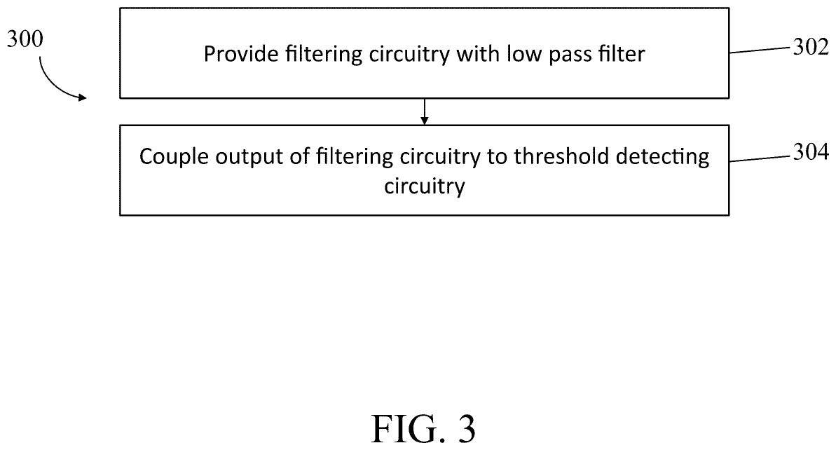

Some aspects of the technology provide for a method of manufacturing a fault detection circuit, for example, the fault detection circuit 100 described herein. FIG. 3 illustrates an example method 300 for manufacturing a circuit for detecting a voltage fault, according to some embodiments of the technology described herein. The method 300 may begin at act 302, where filtering circuitry comprising a low-pass filter is provided. For example, the filtering circuitry may be the filtering circuitry 110 described herein. Providing the filtering circuitry at act 302 may, for example, comprise providing low-pass filtering circuitry with one or more time constants that are specific to the direction of current (e.g., the dual time constant filtering circuitry described herein). Providing the filtering circuitry may comprise assembling the filtering circuitry, in some embodiments, and/or coupling the filtering circuitry to existing circuitry, such as the power circuitry of the device described herein.

At act 304, the output of the filtering circuitry is coupled to threshold detecting circuitry. The threshold detecting circuitry may be the threshold detecting circuitry 120 described herein. The output of the filtering circuitry may be coupled to the input of the threshold detecting circuitry such that signals output from the filtering circuitry may be passed to the threshold detecting circuitry. The fault detection circuit manufactured via the example method 300 may be used, in some embodiments, to detect a DC voltage fault, for example, according to the method 200 shown in FIG. 2.

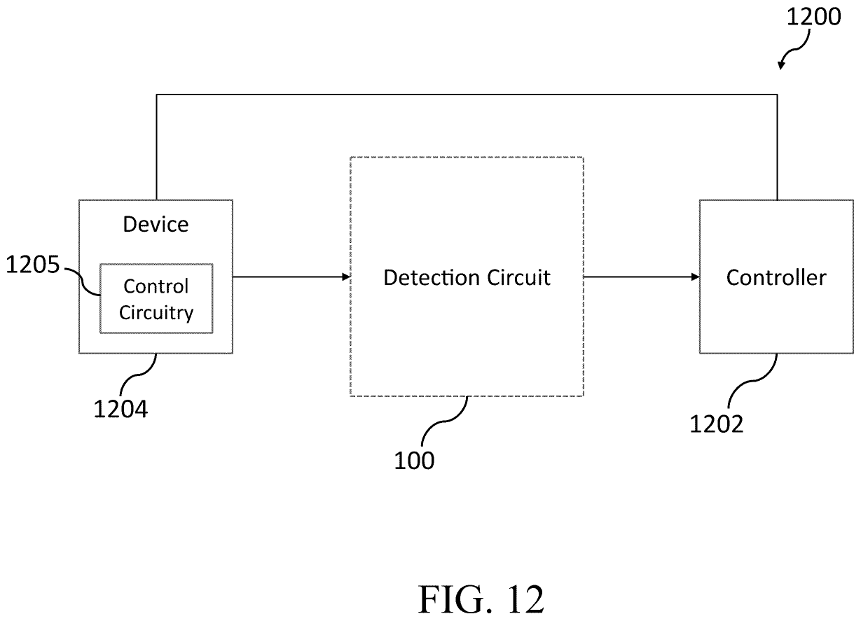

According to some aspects of the technology described herein, there is provided a system comprising a fault detection circuit. For example, FIG. 12 illustrates an example of a system 1200 including a circuit for detecting a voltage fault, according to some embodiments of the technology described herein.

As shown in FIG. 12, the system comprises a device 1204. The device 1204 may be an electrical or electronic device that is powered and/or controlled by control circuitry 1205. For example, in some embodiments, the device 1204 comprises a motor. In some embodiments, the motor may be part of an automated door lock and/or a door operator (e.g., an actuator for opening/closing and/or locking/unlocking a door). In some embodiments, the device 1204 comprises a heater. As described herein, the device may comprise a high duty cycle switched DC voltage bus.

It may be desired to monitor the control circuitry 1205 of the device to detect the occurrence of voltage faults. Accordingly, the device 1204 may be coupled to fault detection circuit 100, described herein. As described herein, fault detection circuit may receive an input signal (e.g., in the illustrated embodiment, from the control circuitry 1205 of the device) and may detect the presence of a fault in the control circuitry 1205 based on the input signal. The fault detection circuit 100 may output an indication, based on the input signal, of whether a voltage fault has occurred in the control circuitry 1204.

The system 1200 further comprises a controller 1202. The controller 1202 may be coupled to the device 1204 and the fault detection circuit 100. In the illustrated embodiment, the controller 1202 is coupled to an output of the fault detection circuit 100. Accordingly, the controller 1202 may receive the output from the fault detection circuit indicating the occurrence of a voltage fault in the control circuitry 1205.

As shown in FIG. 12, the controller 1202 is further coupled to the device 1204. In some embodiments, the controller 1202 may be part of device 1204 (e.g., may be housed within device 1204). In some embodiments, the controller 1202 may be part of control circuitry 1205. The controller 1202 may be configured to control operation of the device 1204. In some embodiments, the controller 1202 may control the device 1204 based on the output of the fault detection circuitry 100. For example, the controller 1202 may control the device 1204 based on detection, by the fault detection circuitry 100, of a fault in the control circuitry 1205 of the device 1204. For example, the controller 1202 may cause the device 1204 to enter a “safe mode” which may include turning off (e.g., disconnecting and/or otherwise removing power from the device 1204) in response to detection of a fault in the control circuitry 1205. The controlling of device 1204 by the controller 1202 in response to detecting a fault in the control circuitry 1205 can help to mitigate and/or prevent side effects of the fault, including damage to components of the device, inability to operate the device partially or fully, and/or dangerous conditions such as undesired operation, electrical shock, fire, or other hazards.

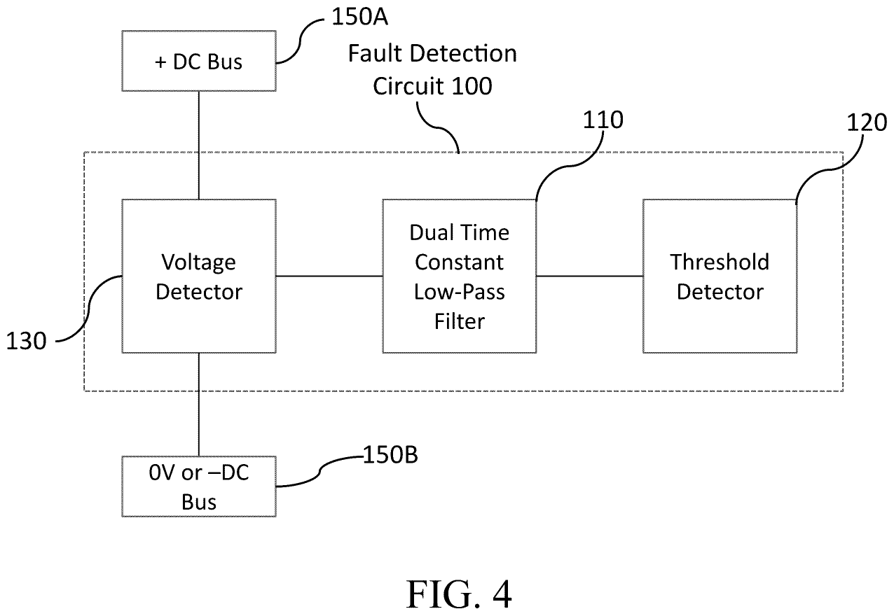

The aspects of the fault detection circuit 100 described herein as well as additional aspects and modifications thereof are further described herein. For example, in some embodiments, the fault detection circuit 100 further comprises a voltage detector. FIG. 4 illustrates another example circuit for detecting a voltage fault, according to some embodiments of the technology described herein. In the illustrated embodiment of FIG. 4, the fault detection circuit 100 further comprises a voltage detector 130.

As shown in FIG. 4, an output of the voltage detector 130 is coupled to an input of the filtering circuitry 110. The voltage detector 130 may function to detect and/or modify (e.g., convert, amplify) input signals (e.g., input power, current, or voltage) to the fault detection circuit 100. For example, in some embodiments, the voltage detector 130 comprises one or more voltage or current transducers, resistors, and/or optocouplers. In embodiments where the voltage detector 130 amplifies input signals, the amplified signal is passed from the voltage detector 130 to the input of the filtering circuitry 110.

An input of the voltage detector 130 is coupled to the positive DC bus 150A, which may be a component of the power circuitry of the device which is being monitored for the occurrent of a fault. In some embodiments, a second input of the voltage detector may be coupled to a second output 150B. The second output 150B may comprise a negative DC bus, in some embodiments. For example, where the power circuitry of the device being monitored outputs positive and negative signals, the second output 150B may comprise the negative DC bus. In some embodiments, the second output 150B may comprise a ground voltage of 0 volts, which may be used as a reference voltage for the voltage detector 130.

As described herein, the fault detection circuit 100 is configured to distinguish between signals occurring during normal operation of the device and signals which are indicative of occurrence of a fault in power circuitry of the device. The signals occurring during normal operation of the device may include pulse width modulation signals. Puls width modulation is a form of signal modulation where the widths of the pulses correspond to specific data values encoded at one end. For example, pulse width modulation may be used to encode a 0 or 1, with longer pulses set equal to 1 and shorter pulses set equal to 0.

In certain cases, the polarity of the power applied to the load is switched back and forth (e.g., to provide holding torque, creating average voltage level, etc.). Accordingly, in some embodiments, the signals occurring during normal operation of the device may include constant polarity reversals. The constant polarity reversals may be intentional reversals of polarity to encode 0 and 1s. For example, negative signals may be set equal to 0 while positive signals may be set equal to 1. Therefore, in some embodiments, the signals output from the power circuitry and input to the fault detection circuit 100 may be negative in some instances.

The fault detection circuit described herein can be implemented with polarity to differentiate between the state of power polarity reversals and a DC fault. If the voltage detector is polarized, meaning its output differentiates between the polarity of the power applied, filtering circuitry and threshold detecting circuitry can be applied to each polarity. In particular, in order to maintain the ability to distinguish between signals occurring during normal operation of the device and signals that are indicative of a fault in power circuitry, the fault detection circuit may include a positive branch for assessing the occurrence of a fault based on positive signals from the power circuitry and a negative branch for assessing the occurrence of a fault based on negative signals from the power circuitry.

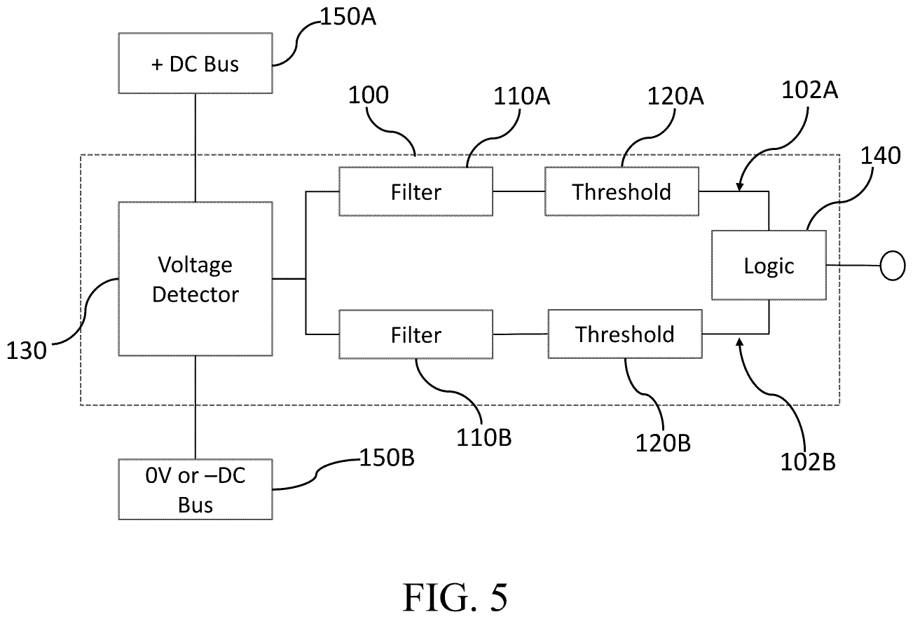

FIG. 5 illustrates another example circuit for detecting a voltage fault, according to some embodiments of the technology described herein. As shown in FIG. 5, the fault detection circuit comprises a positive branch 102A and a negative branch 102B. Starting with the positive branch 102A, the fault detection circuit 100 comprises filtering circuitry 110A, which may be configured in the same or similar manner as filtering circuitry 110 described herein. The fault detection circuit 100 further comprises threshold detecting circuitry 120A, which may be configured in the same or similar manner as threshold detecting circuitry 120 described herein.

Turning to the negative branch 102B, the fault detection circuit 100 comprises filtering circuitry 110B, which may be configured in the same or similar manner as filtering circuitry 110. The fault detection circuit further comprises threshold detecting circuitry 110B, which may be configured in the same or similar manner as threshold detecting circuitry 120.

The outputs of the threshold detecting circuitry 120A and 120B are each coupled to a logic gate 140. For example, the logic gate 140 may be an OR gate, which outputs a signal indicating a fault has been detected if a signal on either the positive branch 102A or the negative branch 102B exceeds the applicable threshold at the respective threshold detecting circuitry 120A-B for that branch. Accordingly, the logic gate 140 can be configured to output an indication that a fault has been detected based on either a positive signal or a negative signal input into the fault detection circuitry 100.

FIG. 6. illustrates another example circuit for detecting a voltage fault, according to some embodiments of the technology described herein. As described herein, the voltage detector may be any component which detects and/or modifies (e.g., converts, amplifies) an input signal. The signal is then passed from the voltage detector 130 to filtering circuitry 110A or 110B. In the illustrated embodiment of FIG. 6, the voltage detector 130 comprises a voltage-to-current transducer. The voltage-to-current transducer converts an input voltage signal into a proportional output current signal.

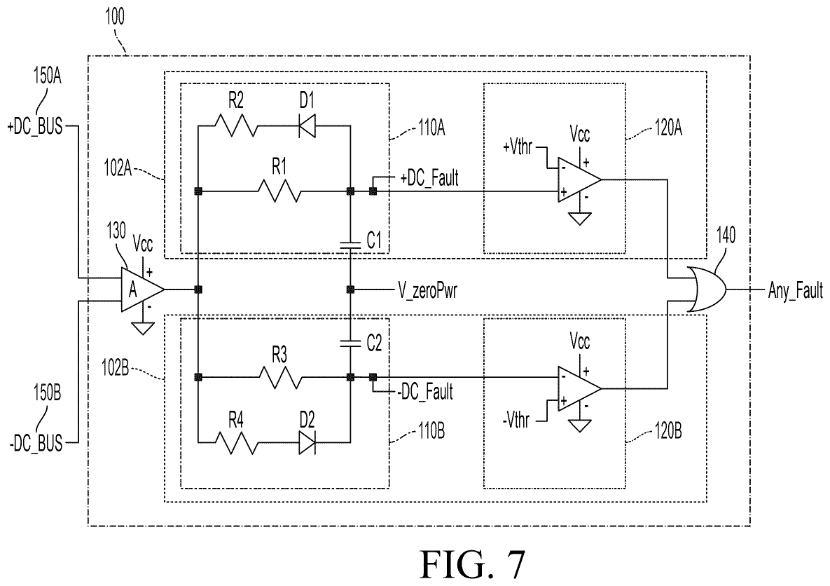

FIG. 7 illustrates another example circuit for detecting a voltage fault, according to some embodiments of the technology described herein. In particular, FIG. 7 illustrates an example implementation of the fault detection circuit 100 using RC circuitry.

As shown in the illustrated embodiment of FIG. 7, the fault detection circuit 100 comprises a voltage detector 130 which receives inputs from positive DC bus 150A and negative DC bus 150B. The output of the voltage detector 130 is then fed into filtering circuitry.

In the illustrated embodiment, the fault detection circuit 100 comprises a positive branch 102A and a negative branch 102B, as described herein. The configuration of the fault detection circuit 100 with positive and negative branches enables the fault detection circuit 100 to distinguish between signals occurring during normal operation of the monitored device and voltage faults, even with the use of constant polarity reversals, as described herein.

Turning to the positive branch 102A of the fault detection circuit 100 first, in the illustrated embodiment of FIG. 7, the filtering circuitry 110A comprises RC circuitry. In particular, the filtering circuitry 110A comprises a capacitor C1, a first signal path comprising a first resistor R1, and a second signal path comprising a second resistor R2 and a diode D1. When a signal flows from left to right (e.g., from the voltage detector 130 towards the threshold detecting circuitry 120A), the signal is forced to flow along the first signal path comprising the first resistor R1, due to diode D1 in the second signal path. Accordingly, signals moving from left to right have a first resistance equal to the value of R1. When a signal flows from right to left, the diode D1 permits flow along the second signal path in addition to the first signal path. Accordingly, signals moving from right to left have parallel signal paths, each with respective resistors, and the resistance of flow from right to left is equal to R₁₊₂=(R1*R2)/(R1+R2). As the equivalent resistance of a parallel network is less than the smallest individual resistor in the combination, regardless of the resistance values of R1 and R2, flow from right to left will have less resistance than flow from left to right.

For the positive branch 102A, charging of the capacitor C1 with positive signals results in signal flow from left to right (e.g., from voltage detector 130 towards capacitor C1) and discharging of the capacitor C1 will result in signal flow from right to left (e.g., from capacitor C1 towards voltage detector 130). Accordingly, charging of the capacitor C1 has a higher resistance signal path than discharging of the capacitor C1.

The time constant of an RC circuit is representative of the time required to charge or discharge the capacitor. The time constant τ is equal to the product of a signal path's resistance and the capacitance of the capacitor (R*C). For charging of the capacitor C1, the time constant τ₁ is equal to R1*C1. For discharging of the capacitor C1, the time constant τ₁ is equal to R₁₊₂*C1. As described herein, the combined resistance R₁₊₂is less than R1. Accordingly, the product of R1*C1 will be larger than the product of R₁₊₂*C1. Therefore, the time constant τ₁ applicable to charging the capacitor C1 is larger than the time constant τ₂ applicable to discharging of the capacitor.

In this manner, discharging of the filtering circuitry 110A, and specifically capacitor C1, occurs more rapidly than charging of the filtering circuitry 110A. For signals that switch between charging and discharging (e.g., between “on” and “off”), the dual time constant of the filtering circuitry 110A prevents charge from accumulating to a threshold level. In some embodiments, the filtering circuitry (e.g., the charging filter and output threshold) can be tuned to create a minimum fault time. For example, the value of the dual time constant applicable to the filtering circuitry may be selected as desired (e.g., by selecting particular resistors and/or capacitors) to achieve a particular value time constant. In this manner, the fault detection circuitry can be adapted to satisfy any system requirements to reject noise or short, self-correcting faults. For example, the positive and/or negative branches of the filtering circuitry described herein can be adapted in this manner.

The charge accumulated at the capacitor C1 is compared to the threshold level using the threshold detecting circuitry 120A. In particular, as there is no potential difference between the top plate of the capacitor and the threshold detecting circuitry 120A, the value of the charge accumulated on the top plate of the capacitor C1 is compared to the threshold level using the threshold detecting circuitry 120A. As described herein, the threshold detecting circuitry 120A may comprise a comparator, as is the case for the illustrated embodiment of FIG. 7. The comparator compares the input signal to a threshold voltage (V_{threshold}). If the input signal to the comparator is greater than the threshold voltage, a positive indication is output from the comparator (e.g., a “1”). Otherwise, if the input signal is not greater than the threshold voltage, a negative indication is output from the comparator (e.g., a “0”). The signal output from the comparator is then input to a logic gate 140 which may output a signal indicating a fault has been detected if the signal input to the OR gate is equal to 1, for example. If the signal input to the OR gate is equal to 0, the logic gate 140 will not output the signal indicating a fault has been detected.

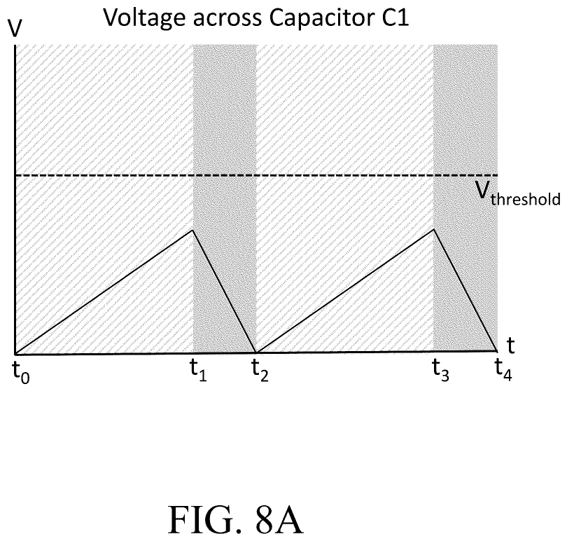

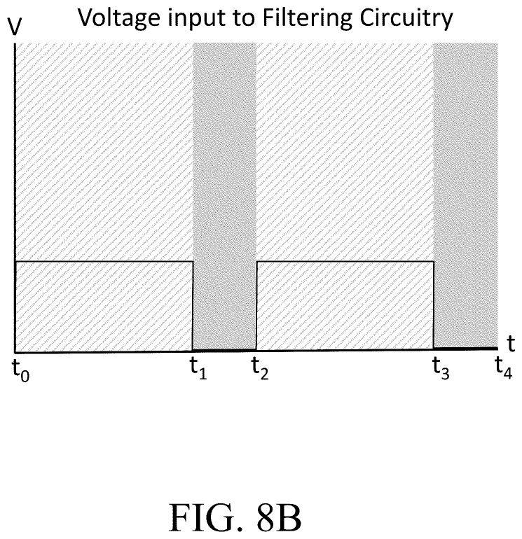

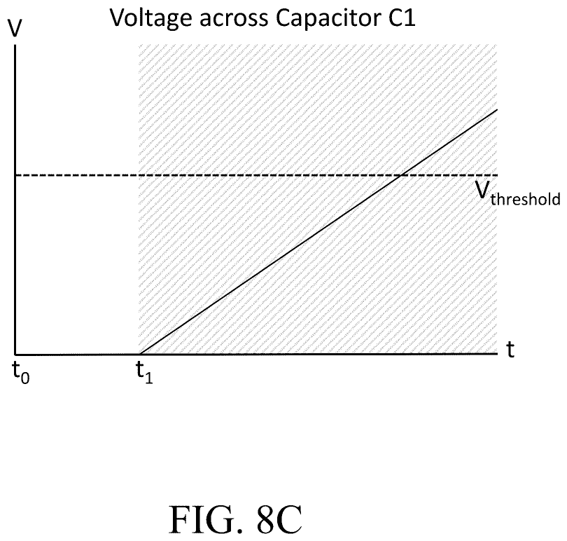

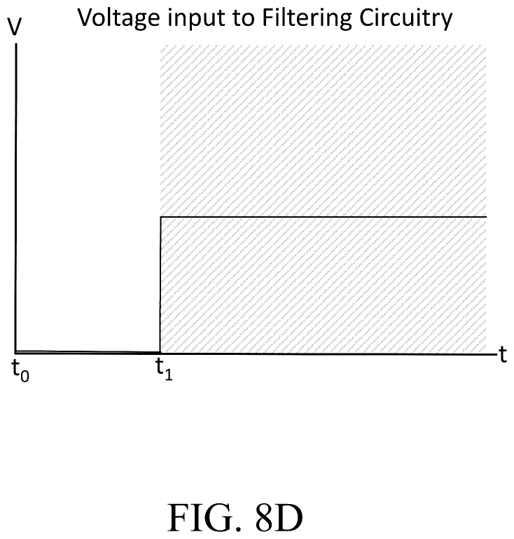

FIG. 8A illustrates an example graph illustrating voltage across the capacitor C1 of the fault detection circuit of FIG. 7, according to some embodiments of the technology described herein. The graph illustrated in FIG. 8A depicts the charge across the capacitor C1 when an oscillating signal is input to the filtering circuitry. In particular, the signal input to the filtering circuitry is a high frequency signal used to power a high duty cycle switched DC bus. Accordingly, the signal applied to the filtering circuitry oscillates between on and off, and is on more often than not.

FIG. 8B illustrates an example graph illustrating voltage input to the filtering circuitry of the fault detection circuit of FIG. 7, according to some embodiments of the technology described herein. In particular, FIG. 8B illustrates an example graph illustrating timing of the oscillating signal applied in FIG. 8A. The oscillating signal may be a signal that occurs during normal operation of the device (e.g., PWM signals). In FIGS. 8A-8B, the time from t₀ to t₁ represents time when the input signal is on and capacitor C1 is being charged. From t₁ to t₂, the input signal is turned off and the capacitor C1 discharges during this period. From t₂ to t₃ the input signal is turned on again, and the capacitor C1 charges. From t₃to t₄, the input signal is again turned off and the capacitor C1 discharges during this period.

FIGS. 8A-8B illustrates that the input signal to the filtering circuitry oscillates between on and off, and in turn, the capacitor C1 oscillates between being charged and being discharged. In addition, FIG. 8A illustrates that the rate at which the capacitor C1 discharges is more rapid than the rate at which the capacitor C1 discharges as represented by the slope of the voltage line during charging periods (t₀ to t₁ and t₂ to t₃) and discharging periods (t₁ to t₂ and t₃ to t₄). Although the input signal is on more often than not, and the charging periods are therefore longer than the discharging periods, charge at the capacitor C1 never accumulates to reach V_{threshold} due to the different rates at which discharging and charging of the capacitor C1 occurs, and in particular configuration of the filtering circuitry to discharge capacitor C1 more rapidly than charging of capacitor C1.

Assuming that the input signal oscillates between on and off frequently enough (even if the input signal is “on” for the vast majority of the time), the configuration of the filtering circuitry to rapidly discharge the capacitor C1 prevents accumulation charge on the capacitor C1. In this manner, the filtering circuitry filters high frequency signals by preventing accumulation of charge from the high frequency signals.

By contrast, if the input signal does not oscillate between on and off with a high frequency, and instead remains on, the capacitor C1 would continue to accumulate charge until it reaches V_{threshold}. For example, FIG. 8C illustrates another example graph illustrating voltage across the capacitor C1 of the fault detection circuit of FIG. 7, according to some embodiments of the technology described herein. The graph illustrated in FIG. 8C depicts charge across the capacitor when a signal arising from a voltage fault is input to the filtering circuitry.

FIG. 8D illustrates an example graph illustrating voltage input to the filtering circuitry of the fault detection circuit of FIG. 7, according to some embodiments of the technology described herein. In FIGS. 8C-8D, the signal input to the filtering circuitry is a signal arising due to a DC voltage fault. Accordingly, the signal does not oscillate between on and off. Because of this, there are no periods of rapid discharging between longer periods of charging. Instead, the charge at the capacitor C1 begins to accumulate when the signal is input to the filtering circuitry at t₁ and is able to continue to accumulate, reaching V_{threshold} after a period of time. In this manner, because the signal arising from a voltage fault is a low frequency signal that does not oscillate on and off, the filtering circuitry does not prevent accumulation of charge from this low frequency signal.

Turning now to the negative branch of the fault detection circuit 102B, the filtering circuitry 110B is configured similarly to filtering circuitry 110A. In particular, if the accumulation of negative charge on the capacitor C2 is considered to be “charging” the capacitor C2, then the negative branch 102B of the filtering circuitry 110 is configured to facilitate discharging of the capacitor more rapidly than charging of the capacitor.

In particular, filtering circuitry 110B comprises a capacitor C2, a first signal path comprising a first resistor R3, and a second signal path comprising a second resistor R4 and a diode D2. The diode D2 functions to limit propagation of signals from right to left to only the first signal path comprising resistor R3 while allowing propagation of signals from left to right on either of the first and second signal paths. Accordingly, signals moving from right to left travel on a signal path having a higher resistance than signals moving from left to right. If signals that move from right to left are considered as charging the capacitor C2 (e.g., making the capacitor more negatively charged) and signals that move from left to right are considered as discharging of the capacitor C2 (e.g., making the capacitor less negatively charged), then in the same manner as filtering circuitry 110A of the positive branch 102A, the negative branch 102B of the filtering circuitry 110B facilitates discharging of the capacitor C2 more rapidly than charging of the capacitor C2.

For example, the resistance of the first signal path comprising R3 is equal to the resistance value of R3. The resistance of the first and second signal paths combined is the combination of the two resistors R3 and R4 in parallel (R₃₊₄=R3*R4)/(R3+R4)) which is less than the resistance of the first signal path alone. The time constant τ₁ applicable to charging of the capacitor C1 from right to left along the first signal path is equal to R3*C2 while the time constant τ₂ applicable to discharging of the capacitor C2 is equal to R₃₊₄*C2. Because the value R3 is greater than the value of R₃₊₄, the time constant τ₁ applicable to charging of the capacitor C2 is larger than the time constant τ₂ applicable to discharging of the capacitor C2. Therefore, the filtering circuitry 110B is configured for slow charging and rapid discharging of the capacitor C2.

For signals that oscillate between on and off, the capacitor C2 oscillates between charging and discharging. In the same manner as described with respect to C1, including in relation to FIGS. 8A-8D for example, the filtering circuitry 110B prevents accumulation of negative charge on the bottom plate of the capacitor C2 arising from signals occurring during normal operation of the device which oscillate between on and off. By contrast, for signals which do not oscillate on and off, such as a signal arising from a DC voltage fault, negative charge is able to accumulate on the capacitor C2.

Threshold detecting circuitry 120B of the negative branch 102B of the fault detection circuit 100 comprises a comparator in the illustrated embodiment. The comparator compares the charge accumulated at the capacitor C2 to the −V_{threshold}, as there is no potential difference between the bottom plate of the capacitor C2 and the input to the comparator. If the charge accumulated at the capacitor C2 exceeds −V_{threshold}, meaning that the signal input to the comparator is more negative than −V_{threshold}, then the comparator outputs a positive indication (e.g., a “1”). If the charge accumulated at the capacitor C2 does not exceed-V threshold, meaning that the signal input to the comparator is less negative than −V_{threshold}, the comparator outputs a negative indication (e.g., a “0”).

The output of the comparator of the threshold detecting circuitry 120B is coupled to the logic gate 140. The logic gate 140, which is an OR gate in the illustrated embodiment of FIG. 7, outputs a signal indicating a fault has been detected if the signal input to OR gate is equal to 1, for example. If the signal input to the OR gate is equal to 0, the logic gate 140 will not output the signal indicating a fault has been detected. Configuring the logic gate 140 as an OR gate allows for outputting the signal indicating a fault has been detected if the signal input to the OR gate on either of the positive branch 102A or the negative branch 102A is equal to 1. Accordingly, the fault detection circuit 100 illustrated in FIG. 7 is configured to detect both positive and negative signals arising from a fault.

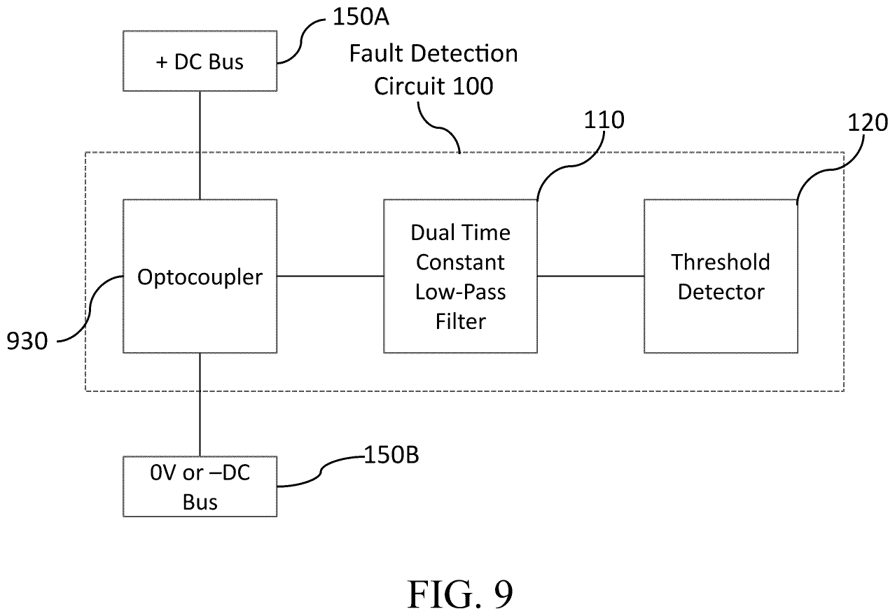

In another embodiment, the fault detection circuitry described herein may include one or more optocouplers FIG. 9 illustrates another example circuit for detecting a voltage fault, according to some embodiments of the technology described herein. In the illustrated embodiment of FIG. 9, the fault detection circuit 100 comprises an optocoupler 930.

An optocoupler is a device containing light-emitting and/or light-sensitive components used to couple isolated circuits. In particular, an optocoupler transfers electrical signals between two isolated circuits using light. Use of an optocoupler can prevent high voltages from affecting the system receiving the signal. In the illustrated embodiment of FIG. 9, the optocoupler 930 is used to implement the functionality described in conjunction with the voltage detector 130 described herein. Accordingly, the optocoupler 930 may perform one or more of the functions of the voltage detector 130 described herein, including, for example, detecting and/or modifying (e.g., converting, amplifying) input signals (e.g., input power, current, or voltage) to the fault detection circuit 100. For example, the optocoupler 930 may be a receiving portion of an optocoupler comprising one or more light sensitive components. In this manner, the optocoupler 930 can isolate the fault detection circuit 100 the power circuitry, and prevent high voltage signals input to the fault detection circuit 100 from damaging the fault detection circuit 100.

In another embodiment, the fault detection circuitry described herein may include one of more current to voltage transducers. For example, as described herein the voltage detector may be any component which detects and/or modifies (e.g., converts, amplifies) an input signal. In some embodiments, the voltage detector 130 described herein comprises a current-to-voltage transducer. The current-to-voltage transducer converts an input current signal into a proportional output voltage signal. Accordingly, the current-to-voltage transducer may perform one or more of the functions of the voltage detector 130 described herein, including, for example, detecting and/or modifying (e.g., converting, amplifying) input signals (e.g., input power, current, or voltage) to the fault detection circuit 100. For example, the voltage-to-current transducer can isolate the fault detection circuit 100 from the power circuitry, and prevent high voltage signals input to the fault detection circuit 100 from damaging the fault detection circuit 100.

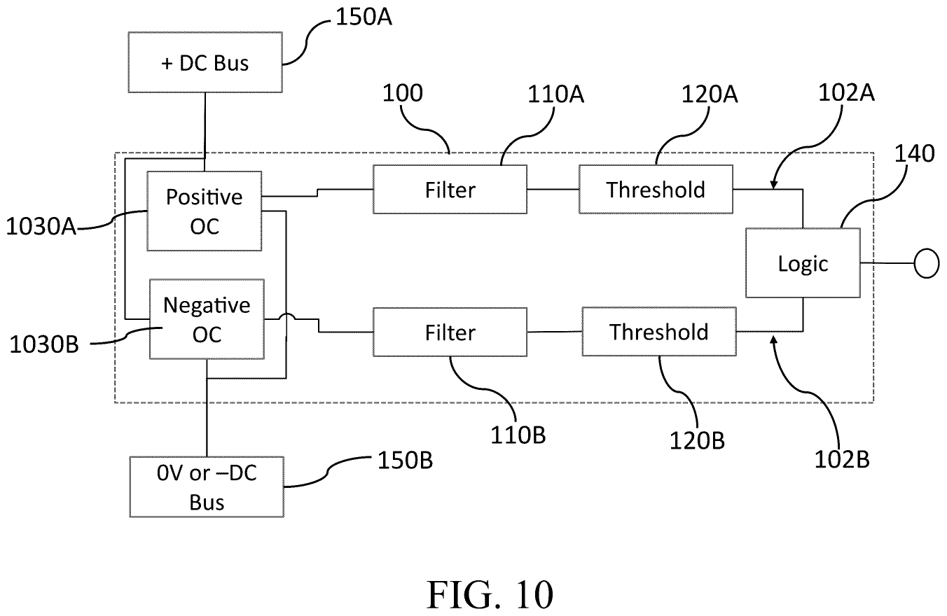

FIG. 10 illustrates another example circuit for detecting a voltage fault, according to some embodiments of the technology described herein. In the illustrated embodiment of FIG. 10, the fault detection circuit 100 comprises a positive optocoupler 1030A and a negative optocoupler 1030B that together perform the functions of the voltage detector 130 described herein.

In particular, the fault detection circuit 100 illustrated in FIG. 10 comprises a positive branch 102A and a negative branch 102B. The positive branch 102A of the fault detection circuit 100 comprises the positive optocoupler 1030A, which has inputs coupled to the positive and negative DC busses 150A-B. The output of the positive optocoupler 1030A is coupled to the filtering circuitry 110A of the positive branch 102A of the fault detection circuit 100. In this manner, the positive optocoupler 1030A detects and/or modifies signals input to the positive branch 102A of the fault detection circuit 100.

The negative branch 102B of the fault detection circuit 100 comprises the negative optocoupler 1030B, which has inputs coupled to the positive and negative DC busses 150A-B. The output of the negative optocoupler 1030B is coupled to the filtering circuitry 110B of the negative branch 102B of the fault detection circuit 100. In this way, the negative optocoupler 1030B detects and/or modifies signals input to the negative branch 102B of the fault detection circuit.

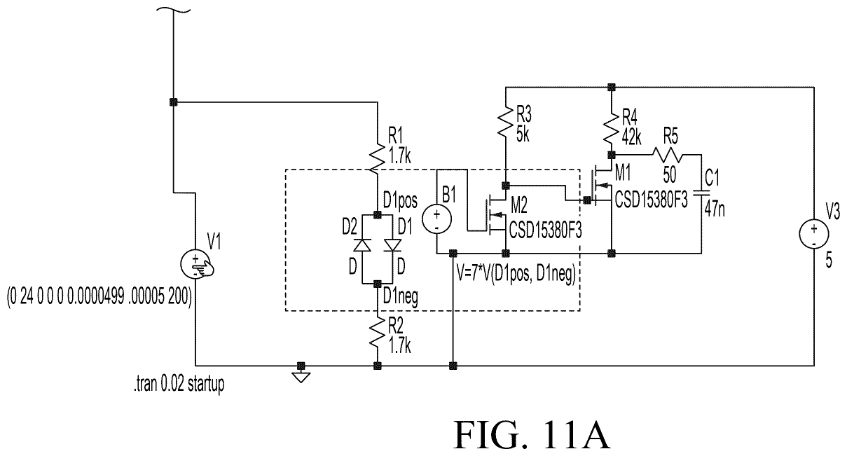

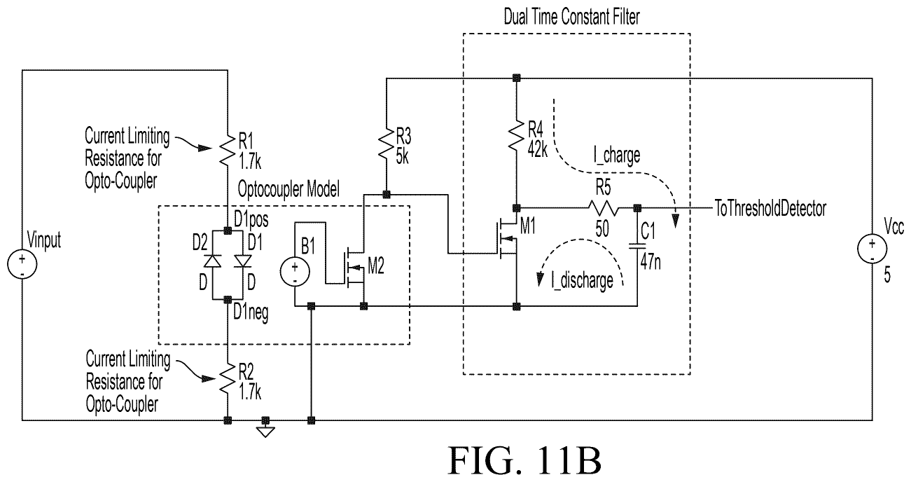

FIG. 11A illustrates another example circuit for detecting a voltage fault, according to some embodiments of the technology described herein. FIG. 11B illustrates the example circuit of FIG. 11A with annotations illustrating components of the dual time constant filter, according to some embodiments of the technology described herein.

For example, in the example shown in FIGS. 11A-B, the circuit comprises positive and negative optocouplers (labeled optocoupler model in FIG. 11B) that together perform the functions of the voltage detector 130 described herein. As shown in FIG. 11B, the example circuit includes resistors R1 and R2 which function to limit the current to the optocoupler model.

FIGS. 11A-B further illustrate filtering circuitry (labeled dual time constant filter in FIG. 11B). The filtering circuitry comprises resistors R4 and R5, capacitor C1, and transistor M1. The direction of current when the capacitor is charging and discharging is shown in FIG. 11B. As described herein, the filtering circuitry is configured such that charging of the capacitor occurs at a different rate than discharging of the capacitor. This is accomplished by implementing a dual time constant for the filtering circuitry. In the illustrated embodiments of FIGS. 11A-B, during charging of the circuitry (the direction of which is denoted by I_charge in FIG. 11B), signals pass through resistors R4 and R5 in series. As the resistors R4 and R5 are arranged in series, the total resistance of the signal path during charging of the capacitor C1 is the sum of R4 and R5. In addition, the resistance of R4 may be relatively high (e.g., 42 k ohms in the illustrated embodiment). Accordingly, the signal path for charging of the circuitry has a high resistance and a higher time constant. During discharging of the circuitry (the direction of which is denoted by I_discharge in FIG. 11B), signals pass only through R5. Accordingly, the total resistance of the signal path during discharging of the circuitry is R5 alone, which is lower than the sum of R4 and R5. As the resistance value of R4 may be selected to be much higher than the resistance of R5, the circuit can be configured such that discharging of capacitor C1 occurs rapidly relative to charging of the capacitor C1. The capacitor C1 is coupled to threshold detecting circuitry. Accordingly, the circuit of FIGS. 11A-B is capable of detecting high voltage DC faults on switched busses, including distinguishing signals resulting from a fault from signals occurring during normal operation of a device.

As described herein, the fault detection circuit can be implemented with polarity, having positive and negative branches to handle both positive and negative signals arising from a fault. It should be appreciated that the example circuit illustrated in FIGS. 11A-B may likewise be implemented to handle such positive and negative signals by including a positive and corresponding negative branch to the dual time constant filter in the same manner as FIGS. 5-7.

Provided herein are example embodiments of the technology.

(1) A circuit for detecting a voltage fault, the circuit comprising: filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and threshold detecting circuitry for determining whether signals output from the filtering circuitry exceeds a threshold voltage, wherein exceedance of the threshold voltage is indicative of the voltage fault.

(2) The circuit of (1), wherein the first time constant is larger than the second time constant such that the charging of the filtering circuitry is slower than the discharging of the filtering circuitry.

(3) The circuit of any of (1)-(2), wherein the filtering circuitry comprises: a first filtering circuit which filters positive input signals having the frequency greater than the threshold and passes positive input signals having the frequency less than the threshold and comprising the first and second time constants; and a second filtering circuit which filters negative input signals having the frequency greater than the threshold and passes negative input signals having the frequency less than the threshold and comprising the first and second time constants.

(4) The circuit of any of (1)-(3), wherein the threshold detecting circuitry comprises a comparator.

(5) The circuit of any of (1)-(4), wherein the filtering circuitry comprises a capacitor.

(6) The circuit of (5), wherein the filtering circuitry comprises a resistor.

(7) The circuit of (5), wherein the filtering circuitry comprises a first resistor and a second resistor in parallel with the first resistor and in series with a diode.

(8) The circuit of any of (1)-(7), further comprising voltage detecting circuitry coupled to an input of the filtering circuitry, the voltage detecting circuitry configured to detect an input signal to the circuit.

(9) The circuit of (8), wherein the voltage detecting circuitry is further configured to scale the input signal to the circuit.

(10) The circuit of (8), wherein the voltage detecting circuitry comprises an amplifier.

(11) The circuit of (8), wherein the voltage detecting circuitry comprises an optocoupler.

(12) The circuit of any of (1)-(11), wherein the filtering circuitry comprises a low-pass filter.

(13) A method of manufacturing a circuit for detecting a voltage fault, the method comprising: providing filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and coupling threshold detecting circuitry to an output of the filtering circuitry, the threshold detecting circuitry for determining whether signals output from the filtering circuitry exceeds a threshold voltage, wherein exceedance of the threshold voltage is indicative of the voltage fault.

(14) The method of (13), wherein the first time constant is larger than the second time constant such that the charging of the filtering circuitry is slower than the discharging of the filtering circuitry.

(15) The method of any of (13)-(14), wherein providing the filtering circuitry comprises: providing a first filtering circuit which filters positive input signals having the frequency greater than the threshold and passes positive input signals having the frequency less than the threshold and comprising the first and second time constants; and providing a second filtering circuit which filters negative input signals having the frequency greater than the threshold and passes negative input signals having the frequency less than the threshold and comprising the first and second time constants.

(16) The method of any of (13)-(15), wherein the threshold detecting circuitry comprises a comparator.

(17) The method of any of (13)-(16), wherein the filtering circuitry comprises a capacitor.

(18) The method of (17), wherein the filtering circuitry comprises a resistor.

(19) The method of (17), wherein the filtering circuitry comprises a first resistor and a second resistor in parallel with the first resistor and in series with a diode.

(20) The method of any of (13)-(19), further comprising providing voltage detecting circuitry and coupling the voltage detecting circuitry to an input of the filtering circuitry, the voltage detecting circuitry configured to detect an input signal to the circuit.

(21) The method of (20), wherein the voltage detecting circuitry is further configured to scale the input signal to the circuit.

(22) The method of (20) wherein the voltage detecting circuitry comprises an amplifier.

(23) The method of (20), wherein the voltage detecting circuitry comprises an optocoupler.

(24) The method of any of (13)-(23), wherein the filtering circuitry comprises a low-pass filter.

(25) A method for detecting a voltage fault, the method comprising: filtering, with filtering circuitry comprising a first time constant applicable to charging of the filtering circuitry and a second time constant different than the first time constant applicable to discharging of the filtering circuitry, input signals having a frequency greater than a threshold and passing input signals having a frequency less than the threshold; determining, with threshold detecting circuitry, whether signals output from the filtering circuitry exceeds a threshold voltage; and detecting, based on exceedance of the threshold voltage, the voltage fault.

(26) The method of (25), wherein the first time constant is larger than the second time constant such that the charging of the filtering circuitry is slower than the discharging of the filtering circuitry.

(27) The method of any of (25)-(26), wherein the filtering circuitry comprises: a first filtering circuit which filters positive input signals having the frequency greater than the threshold and passes positive input signals having the frequency less than the threshold and comprising the first and second time constants; and a second filtering circuit which filters negative input signals having the frequency greater than the threshold and passes negative input signals having the frequency less than the threshold and comprising the first and second time constants.

(28) The method of any of (25)-(27), wherein the threshold detecting circuitry comprises a comparator.

(29) The method of any of (25)-(28), wherein the filtering circuitry comprises a capacitor.

(30) The method of (29), wherein the filtering circuitry comprises a resistor.

(31) The method of (29), wherein the filtering circuitry comprises a first resistor and a second resistor in parallel with the first resistor and in series with a diode.

(32) The method of any of (25)-(31), further comprising detecting, with voltage detecting circuitry coupled to an input of the filtering circuitry, an input signal to the circuit.

(33) The method of (32), further comprising scaling, with the voltage detecting circuitry, the input signal to the circuit.

(34) The method of (32), wherein the voltage detecting circuitry comprises an amplifier.

(35) The method of (32), wherein the voltage detecting circuitry comprises an optocoupler.

(36) The method of any of (25)-(35), wherein the filtering circuitry comprises a low-pass filter.

(37) A system comprising: a device powered by power circuitry; and a circuit for detecting a voltage fault in the power circuitry, the circuit comprising: filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and threshold detecting circuitry for determining whether signals output from the filtering circuitry exceeds a threshold voltage, wherein exceedance of the threshold voltage is indicative of the voltage fault.

(38) The system of (37), further comprising at least one controller configured to adjust operation of the device in response to detection of the voltage fault.

(39) The system of any of (37)-(38), wherein the device comprises a motor.

(40) The system of any of (37)-(39), wherein the first time constant is larger than the second time constant such that the charging of the filtering circuitry is slower than the discharging of the filtering circuitry.

(41) The system of any of (37)-(40), wherein the filtering circuitry comprises: a first filtering circuit which filters positive input signals having the frequency greater than the threshold and passes positive input signals having the frequency less than the threshold and comprising the first and second time constants; and a second filtering circuit which filters negative input signals having the frequency greater than the threshold and passes negative input signals having the frequency less than the threshold and comprising the first and second time constants.

(42) The system of any of (37)-(41), wherein the threshold detecting circuitry comprises a comparator.

(43) The system of any of (37)-(42), wherein the filtering circuitry comprises a capacitor.

(44) The system of (43), wherein the filtering circuitry comprises a resistor.

(45) The system of (43), wherein the filtering circuitry comprises a first resistor and a second resistor in parallel with the first resistor and in series with a diode.

(46) The system of any of (37)-(45), wherein the circuit further comprises voltage detecting circuitry coupled to an input of the filtering circuitry, the voltage detecting circuitry configured to detect an input signal to the circuit.

(47) The system of (46), wherein the voltage detecting circuitry is further configured to scale the input signal to the circuit.

(48) The system of (46), wherein the voltage detecting circuitry comprises an amplifier.

(49) The system of (46), wherein the voltage detecting circuitry comprises an optocoupler.

(50) The system of any of (37)-(49), wherein the filtering circuitry comprises a low-pass filter.

Embodiments of the above-described techniques can be implemented in any of numerous ways. For example, the embodiments may be implemented using hardware, software, or a combination thereof. When implemented in software, the software code can be executed on any suitable processor or collection of processors, whether provided in a single computer or distributed among multiple computers.

Such processors may be implemented as integrated circuits, with one or more processors in an integrated circuit component, including commercially available integrated circuit components known in the art by names such as CPU chips, GPU chips, microprocessor, microcontroller, or co-processor. Alternatively, a processor may be implemented in custom circuitry, such as an ASIC, or semicustom circuitry resulting from configuring a programmable logic device. As yet a further alternative, a processor may be a portion of a larger circuit or semiconductor device, whether commercially available, semi-custom or custom. As a specific example, some commercially available microprocessors have multiple cores such that one or a subset of those cores may constitute a processor. Though, a processor may be implemented using circuitry in any suitable format.

Further, it should be appreciated that a computer may be embodied in any of a number of forms, such as a rack-mounted computer, a desktop computer, a laptop computer, or a tablet computer. Additionally, a computer may be embedded in a device not generally regarded as a computer but with suitable processing capabilities, including a Personal Digital Assistant (PDA), a smart phone or any other suitable portable or fixed electronic device.

Also, a computer may have one or more input and output devices. These devices can be used, among other things, to present a user interface. Examples of output devices that can be used to provide a user interface include printers or display screens for visual presentation of output and speakers or other sound generating devices for audible presentation of output. Examples of input devices that can be used for a user interface include keyboards, and pointing devices, such as mice, touch pads, and digitizing tablets. As another example, a computer may receive input information through speech recognition or in other audible format.

Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

Also, the various methods or processes outlined herein may be coded as software that is executable on one or more processors that employ any one of a variety of operating systems or platforms. Additionally, such software may be written using any of a number of suitable programming languages and/or programming or scripting tools, and also may be compiled as executable machine language code or intermediate code that is executed on a framework or virtual machine.

In this respect, the technology described herein may be embodied as a computer readable storage medium (or multiple computer readable media) (e.g., a computer memory, one or more floppy discs, compact discs (CD), optical discs, digital video disks (DVD), magnetic tapes, flash memories, circuit configurations in Field Programmable Gate Arrays or other semiconductor devices, or other tangible computer storage medium) encoded with one or more programs that, when executed on one or more computers or other processors, perform methods that implement the various embodiments of the technology described herein. As is apparent from the foregoing examples, a computer readable storage medium may retain information for a sufficient time to provide computer-executable instructions in a non-transitory form. Such a computer readable storage medium or media can be transportable, such that the program or programs stored thereon can be loaded onto one or more different computers or other processors to implement various aspects of the present technology as described above. As used herein, the term “computer-readable storage medium” encompasses only a computer-readable medium that can be considered to be a manufacture (i.e., article of manufacture) or a machine. Alternatively or additionally, the technology described herein may be embodied as a computer readable medium other than a computer-readable storage medium, such as a propagating signal.

The terms “program” or “software” are used herein in a generic sense to refer to any type of computer code or set of computer-executable instructions that can be employed to program a computer or other processor to implement various aspects of technology described herein. Additionally, it should be appreciated that according to one aspect of this embodiment, one or more computer programs that when executed perform methods of the present technology need not reside on a single computer or processor, but may be distributed in a modular fashion amongst a number of different computers or processors to implement various aspects of the present technology.

Computer-executable instructions may be in many forms, such as program modules, executed by one or more computers or other devices. Generally, program modules include routines, programs, objects, components, data structures, etc. that perform particular tasks or implement particular abstract data types. Typically the functionality of the program modules may be combined or distributed as desired in various embodiments.

Also, data structures may be stored in computer-readable media in any suitable form. For simplicity of illustration, data structures may be shown to have fields that are related through location in the data structure. Such relationships may likewise be achieved by assigning storage for the fields with locations in a computer-readable medium that conveys relationship between the fields. However, any suitable mechanism may be used to establish a relationship between information in fields of a data structure, including through the use of pointers, tags or other mechanisms that establish relationship between data elements.

Various aspects of the present technology may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Also, the technology described herein may be embodied as a method, examples of which have been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

Various events/acts are described herein as occurring or being performed at a specified time. One of ordinary skill in the art would understand that such events/acts may occur or be performed at approximately the specified time.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The terms “approximately,” “substantially,” and “about” may be used to mean within ±20% of a target value in some embodiments, within ±10% of a target value in some embodiments, within ±5% of a target value in some embodiments, and yet within ±2% of a target value in some embodiments. The terms “approximately” and “about” may include the target value.

Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described several aspects of at least one embodiment of the technology, it is to be appreciated that various alterations, modifications, and improvements will readily occur to those skilled in the art.

Such alterations, modifications, and improvements are intended to be part of this disclosure, and are intended to be within the spirit and scope of the disclosure. Further, though advantages of the present technology are indicated, it should be appreciated that not every embodiment of the technology will include every described advantage. Some embodiments may not implement any features described as advantageous herein and in some instances. Accordingly, the foregoing description and drawings are by way of example only.

What is claimed is:

1. A circuit for detecting a voltage fault, the circuit comprising:
filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and
threshold detecting circuitry for determining whether signals output from the filtering circuitry exceeds a threshold voltage, wherein exceedance of the threshold voltage is indicative of the voltage fault.

2. The circuit of claim 1, wherein the first time constant is larger than the second time constant such that the charging of the filtering circuitry is slower than the discharging of the filtering circuitry.

3. The circuit of claim 1, wherein the filtering circuitry comprises:
a first filtering circuit which filters positive input signals having the frequency greater than the threshold and passes positive input signals having the frequency less than the threshold and comprising the first and second time constants; and
a second filtering circuit which filters negative input signals having the frequency greater than the threshold and passes negative input signals having the frequency less than the threshold and comprising the first and second time constants.

4. The circuit of claim 1, wherein the threshold detecting circuitry comprises a comparator.

5. The circuit of claim 1, wherein the filtering circuitry comprises a capacitor.

6. The circuit of claim 5, wherein the filtering circuitry comprises a resistor.

7. The circuit of claim 5, wherein the filtering circuitry comprises a first resistor and a second resistor in parallel with the first resistor and in series with a diode.

8. The circuit of claim 1, further comprising voltage detecting circuitry coupled to an input of the filtering circuitry, the voltage detecting circuitry configured to detect an input signal to the circuit.

9. The circuit of claim 8, wherein the voltage detecting circuitry is further configured to scale the input signal to the circuit.

10. The circuit of claim 8, wherein the voltage detecting circuitry comprises an amplifier.

11. The circuit of claim 8, wherein the voltage detecting circuitry comprises an optocoupler.

12. The circuit of claim 1, wherein the filtering circuitry comprises a low-pass filter.

13. A method of manufacturing a circuit for detecting a voltage fault, the method comprising:
providing filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and
coupling threshold detecting circuitry to an output of the filtering circuitry, the threshold detecting circuitry for determining whether signals output from the filtering circuitry exceeds a threshold voltage, wherein exceedance of the threshold voltage is indicative of the voltage fault.

14. The method of claim 13, wherein the first time constant is larger than the second time constant such that the charging of the filtering circuitry is slower than the discharging of the filtering circuitry.

15. The method of claim 13, wherein providing the filtering circuitry comprises:
providing a first filtering circuit which filters positive input signals having the frequency greater than the threshold and passes positive input signals having the frequency less than the threshold and comprising the first and second time constants; and
providing a second filtering circuit which filters negative input signals having the frequency greater than the threshold and passes negative input signals having the frequency less than the threshold and comprising the first and second time constants.

16. The method of claim 13, wherein the threshold detecting circuitry comprises a comparator.

17. The method of claim 13, wherein the filtering circuitry comprises a capacitor.

18. The method of claim 17, wherein the filtering circuitry comprises a resistor.

19. The method of claim 17, wherein the filtering circuitry comprises a first resistor and a second resistor in parallel with the first resistor and in series with a diode.

20. A system comprising:
a device powered by power circuitry; and
a circuit for detecting a voltage fault in the power circuitry, the circuit comprising:
filtering circuitry comprising a first time constant applicable to charging of the filtering circuitry and a second time constant different than the first time constant applicable to discharging of the filtering circuitry, and the filtering circuitry filters input signals having a frequency greater than a threshold and passes input signals having a frequency less than the threshold; and
threshold detecting circuitry for determining whether signals output from the filtering circuitry exceeds a threshold voltage, wherein exceedance of the threshold voltage is indicative of the voltage fault.
